(19) United States
(12) Patent Application Publication
(10) Pub. No.: US 2006/0291310 A1
(43) Pub. Date: Dec. 28, 2006

(54) Block word line precharge circuit of flash memory device

(75) Inventor: Young Su Kang, Kyeongki-do (KR)

Correspondence Address: MAYER, BROWN, ROWE & MAW LLP, 1909 K STREET, N.W., WASHINGTON, DC, 20006, US

(73) Assignee: Hynix Semiconductor Inc.

(21) Appl. No.: 11/473,027

(22) Filed: Jun. 23, 2006

(30) Foreign Application Priority Data
Jun. 24, 2005 (KR) 2005-55021

(51) Int. Cl. G11C 7/00

(52) U.S. Cl. 365/203; 365/185.11

(57) ABSTRACT

A block word line precharge circuit that precharges a block word line connected to the gates of transistors, for transferring bias of global word lines to local word lines, respectively. During a precharge period of the block word line, a program voltage, a read voltage and a pass voltage are all shared. Accordingly, a precharge time of the block word line can be reduced.

### BACKGROUND

1. Field of the Invention

The present invention relates to a block word line precharge circuit of a flash memory device. More particularly, the present invention relates to a circuit for precharging a block word line connected to the gates of transistors, for transferring bias of global word lines to local word lines, respectively.

2. Discussion of Related Art

A flash memory cell is divided into a number of blocks. The flash memory cell precharges selected block word lines and then discharges the remaining non-selected block word lines. Each block word line is precharged by a block word line precharge circuit.

FIG. 1 is a circuit diagram of a block word line precharge circuit in the related art.

Referring to FIG. 1, the block word line precharge circuit includes a program pump circuit 10, a block word line precharge unit 20, and a word line switching unit 30.

A block word line BLKWL is precharged through precharge control signals (GA/GB). The control signals (GA/GB) are applied with a high voltage (VPP), which is output from the program pump circuit 10, through high voltage switching circuits 21, 22. Accordingly, if the high voltage (VPP) has not risen to a sufficient level, the level of the high voltage (VPP) of the block word line BLKWL is lowered. Therefore, the precharge control signal (GA/GB) cannot sufficiently transfer the bias of a global word line GWL to a local word line LWL.

For example, as shown in FIG. 2, if it takes a long time for a voltage to rise to a high voltage, approximately 18 V because the high voltage (VPP) output from the program pump circuit 10 is low, the voltage level of the block word line BLKWL can be sufficiently precharged by lengthening a precharge time (Tpre) of the precharge control signals (GA/GB). If the block word line precharge time (Tpre) is lengthened, however, there is a disadvantage in that a program time is extended in proportion to the extended precharge time.

In a real device, the size of a pump is inevitably very limited since it is related to a net die number, and so on. Accordingly, there is a need for a method capable of reducing a time taken to precharge the block word line with the same pump size.

### SUMMARY OF THE INVENTION

In an embodiment of the present invention, a device is provided that can reduce a precharge time of a block word line by sharing a program voltage, a read voltage, and a pass voltage during the precharge period of the block word line.

According to an embodiment of the present invention, there is provided a block word line precharge circuit of a flash memory device, wherein the block word line precharge circuit precharges a block word line connected to gates of transistors, for transferring bias of global word lines to local word lines, respectively, the block word line precharge circuit including a program pump circuit that generates a high voltage, a pass pump circuit that generates a pass voltage, a read pump circuit that generates a read voltage, and a block word line precharge unit which receives the high voltage, the pass voltage, and the read voltage during a precharge period in which the pass voltage and the read voltage rise and precharge the block word line.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a circuit diagram of a block word line precharge circuit in the related art;

FIG. 2 is a timing diagram illustrating waveforms of signals of FIG. 1;

FIG. 3 is a circuit diagram of a block decoder according to an embodiment of the present invention; and

FIG. 4 is a timing diagram illustrating exemplary waveforms of signals described in FIG. 3.

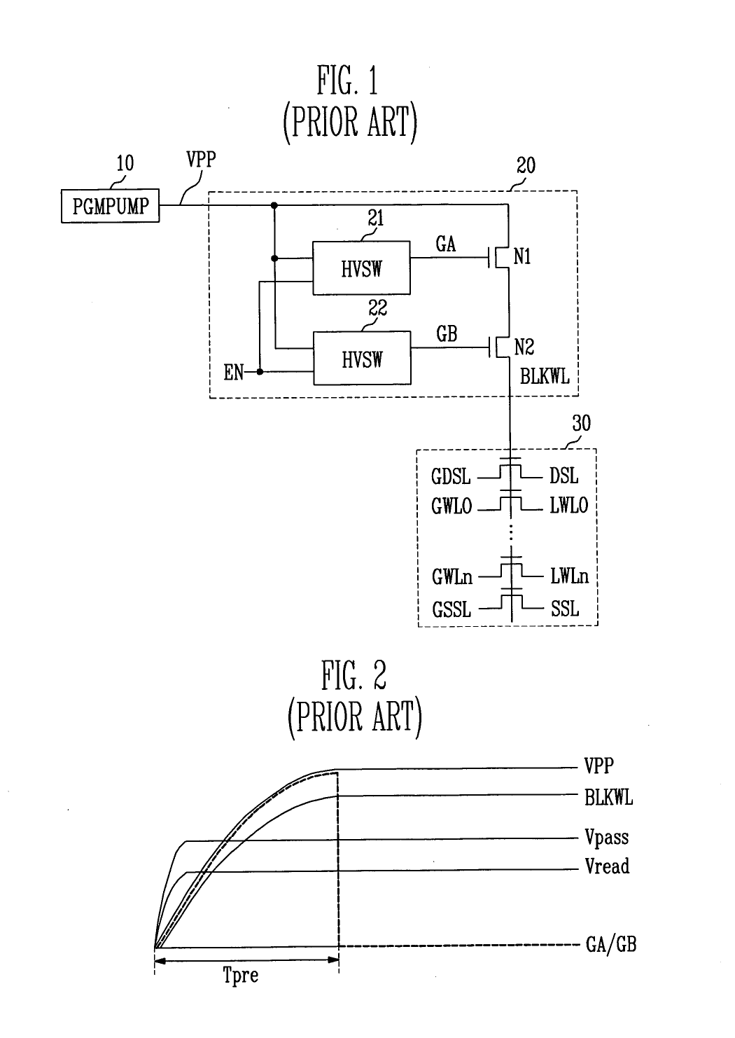

### DETAILED DESCRIPTION OF EMBODIMENTS

In the following detailed description, only certain exemplary embodiments of the present invention have been shown and described simply by way of illustration. As those skilled in the art will realize, the described embodiments may be modified in various different ways, all without departing from the spirit or scope of the present invention. Accordingly, the drawings and description are to be regarded as illustrative in nature and not restrictive. Like reference numerals designate like elements throughout.

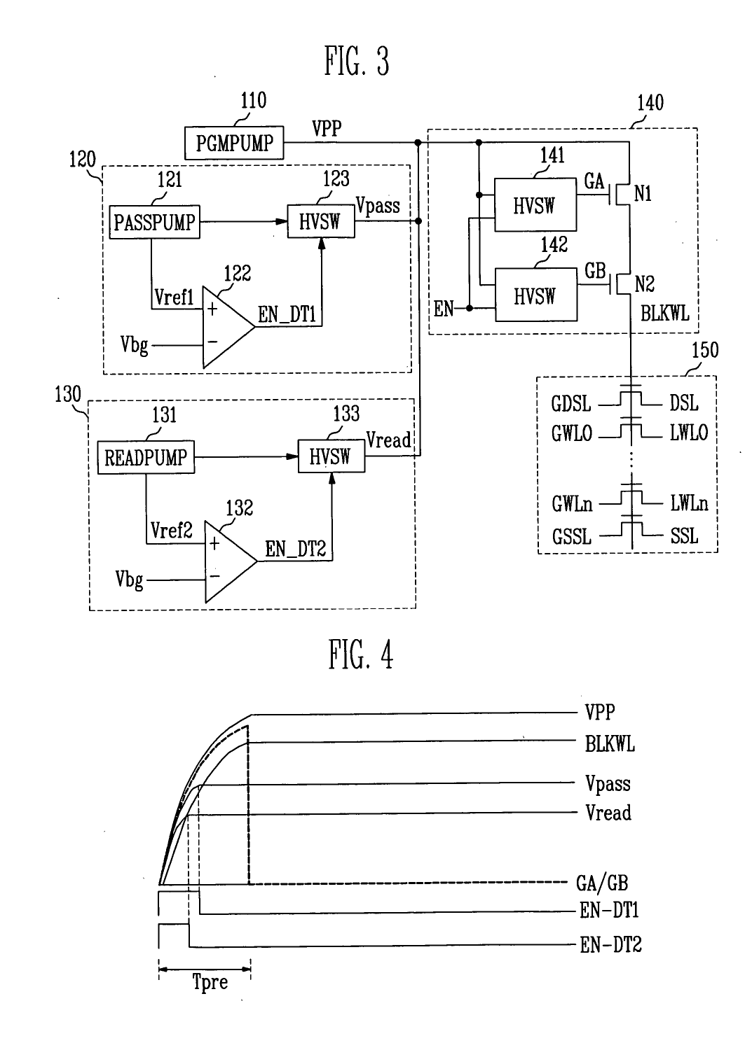

FIG. 3 is a circuit diagram of a block decoder according to an embodiment of the present invention.

Referring to FIG. 3, the block word line precharge circuit includes a program pump circuit 110, a pass pump circuit 120, a read pump circuit 130, a block word line precharge unit 140, and a word line switching unit 150.

The program pump circuit 110 performs a pumping operation to generate a high voltage (VPP) (i.e., a program voltage). The pass pump circuit 120 performs a pumping operation to generate a pass voltage (Vpass) (a program-prohibiting voltage for prohibiting program). The read pump circuit 130 performs a pumping operation to generate a read voltage (Vread).

The pass pump circuit 120 includes a pass pump 121, a voltage controller 122, and a high voltage switch 123.

The pass pump 121 performs the pumping operation and generates the pass voltage (Vpass).

The voltage controller 122 compares a pass reference voltage (Vref1) generated from the pass pump 121 and a bandgap reference voltage (Vbg). If the pass reference voltage (Vref1) is lower than the bandgap reference voltage (Vbg), the voltage controller 122 outputs a detection signal (EN_DT1) as a logical high. If the pass reference voltage (Vref1) is higher than the bandgap reference voltage (Vbg), the voltage controller 122 outputs the detection signal (EN_DT1) as a logical low.

The high voltage switch 123 transfers the pass voltage (Vpass), which is output from the pass pump 121, to a line on which the high voltage (Vpp) is loaded when the detection signal (EN_DT1) becomes a logical high (i.e., in a precharge period), but does not transfer the pass voltage (Vpass), which is output from the pass pump 121, to the line on which the high voltage (Vpp) is loaded when the detection signal (EN_DT1) become a logical low (i.e., after the pass voltage (Vpass) becomes a target level).

The read pump circuit 130 includes a read pump 131, a voltage controller 132, and a high voltage switch 133.

The read pump 131 performs a pumping operation to generate the read voltage (Vread).

The voltage controller 132 compares a read reference voltage (Vref2) generated from the read pump 131 and a bandgap reference voltage (Vbg). If the read reference voltage (Vref2) is lower than the bandgap reference voltage (Vbg), the voltage controller 132 outputs a detection signal (EN_DT2) as a logical high. If the read reference voltage (Vref2) is higher than the bandgap reference voltage (Vbg), the voltage controller 132 outputs the detection signal (EN_DT2) as a logical low. When the detection signal (EN_DT2) becomes a logical low (i.e., after the read voltage (Vread) becomes a target level), the voltage controller 132 does not transfer the read voltage (Vread), which is output from the read pump 131, to a line on which the high voltage (Vpp) is loaded.

The above-mentioned voltage controllers 122, 132 always exist in a real pump circuit and are thus not required to be newly added.

The high voltage switches 123, 133 cause the outputs of the pumps 110, 121, and 131 to be shared when the detection signals (EN_DT1, 2) are a logical high (i.e., in the precharge period) and causes the outputs of the pumps 110, 121, and 131 to be separated from one another when the detection signals (EN_DT1, 2) are a logical low (i.e., not the precharge period).

The block word line precharge unit 140 includes high voltage switches 141, 142, and NMOS transistors N1, N2.

The high voltage switches 141, 142 respectively make the levels of the precharge control signals (GA, GB) a voltage level in which the high voltage (VPP), the pass voltage (Vpass), and the read voltage (Vread) are added. The high voltage switches 141, 142 operate when an enable signal (EN) is input as a logical high.

The NMOS transistors N1, N2 receive the precharge control signals (GA, GB), respectively, and precharge the block word line BLKWL with a voltage level in which the high voltage (VPP), the pass voltage (Vpass), and the read voltage (Vread) are added. In this case, the precharge control signals (GA, GA) become a target level faster than the related art and the precharge time (Tpre) of the block word line BLKWL becomes short in comparison with the related art.

As described above, in an embodiment of the present invention, the output voltages of the program pump circuit 110, the pass pump circuit 120, and the read pump circuit 130 are shared during the rising operation of the initial pump circuit (i.e., the precharge period) in order to reduce the precharge time (Tpre) of the block word line BLKWL.

In other words, in the related art, only the program pump circuit 110 was used during the rising operation of the initial pump circuit. In an embodiment of the present invention, however, during the rising operation of the initial pump circuit, the pass pump circuit 120 and the read pump circuit 130 are shared as well as the program pump circuit 110. Accordingly, the voltage levels of the precharge control signals (GA/GB) can be raised faster than the related art. In addition, after the voltages (Vpass, Vread) rise up to the highest voltage level (i.e., a target level), the program pump circuit 110, the pass pump circuit 120, and the read pump circuit 130 are separated from one another.

FIG. 4 shows the block word line precharge time (Tpre) according to an embodiment of the present invention.

From FIG. 4, it can be seen that the precharge levels of the precharge control signals (GA/GB) become high in comparison with the related art and the precharge time (Tpre) thus becomes much faster in comparison with the related art.

As described above, according to an embodiment of the present invention, since the block word line precharge time is reduced, a program time can be effectively reduced. As a result, chip performance can be improved.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A block word line precharge circuit of a flash memory device, wherein the block word line precharge circuit precharges a block word line connected to gates of transistors, for transferring bias of global word lines to local word lines, respectively, the block word line precharge circuit comprising:
a program pump circuit that generates a high voltage;
a pass pump circuit that generates a pass voltage;
a read pump circuit that generates a read voltage; and
a block word line precharge unit which receives the high voltage, the pass voltage, and the read voltage that are connected during a precharge period in which the pass voltage and the read voltage rise and precharge the block word line.

2. The block word line precharge circuit as claimed in claim 1, wherein the pass pump circuit and the read pump circuit are connected to a program pump circuit during the precharge period, and are separated from the program pump circuit after the pass voltage and the read voltage rise up to a predetermined highest voltage level.

3. The block word line precharge circuit as claimed in claim 1, wherein the pass pump circuit comprises:
a pump that generates the pass voltage;
a voltage controller which compares a reference voltage output from the pump and a bandgap reference voltage and outputs a detection signal; and
a high voltage switch that transfers the pass voltage to the block word line precharge unit in response to the detection signal.

4. The block word line precharge circuit as claimed in claim 3, wherein the voltage controller operates the high voltage switch during the precharge period in which the pass voltage rises, and does not operate the high voltage switch after the pass voltage rises up to a predetermined highest voltage level.

5. The block word line precharge circuit as claimed in claim 3, wherein the voltage controller outputs the detection signal as a logical high if the reference voltage is lower than the bandgap reference voltage and thus operates the high voltage switch, and outputs the detection signal as a logical low if the reference voltage is higher than the bandgap reference voltage and thus does not operate the high voltage switch.

6. The block word line precharge circuit as claimed in claim 1, wherein the read pump circuit comprises:
a pump that generates the read voltage;
a voltage controller which compares a reference voltage output from the pump and a bandgap reference voltage and outputs a detection signal; and
a high voltage switch that transfers the read voltage to the block word line precharge unit in response to the detection signal.

7. The block word line precharge circuit as claimed in claim 6, wherein the voltage controller operates the high voltage switch during the precharge period in which the read voltage rises, and does not operate the high voltage switch after the read voltage rises up to a predetermined highest voltage level.

8. The block word line precharge circuit as claimed in claim 6, wherein the voltage controller outputs the detection signal as a logical high if the reference voltage is lower than the bandgap reference voltage and thus operates the high voltage switch, and outputs the detection signal as a logical low if the reference voltage is higher than the bandgap reference voltage and thus does not operate the high voltage switch.
